(19) United States
(12) Patent Application Publication
(10) Pub. No.: US 2026/0150189 A1
(43) Pub. Date: May 28, 2026

(54) PRINTED CIRCUIT BOARD

(71) Applicant: SAMSUNG ELECTRO-MECHANICS CO., LTD., Suwon-si (KR)

(72) Inventor: Chan Hoon KO, Suwon-si (KR)

(73) Assignee: SAMSUNG ELECTRO-MECHANICS CO., LTD., Suwon-si (KR)

(21) Appl. No.: 19/225,353

(22) Filed: Jun. 2, 2025

(30) Foreign Application Priority Data
Nov. 25, 2024 (KR) 10-2024-0169768

(51) Int. Cl. H05K 1/09; H05K 1/18; H05K 3/46

(52) U.S. Cl. CPC H05K 1/09; H05K 1/181; H05K 3/4644; H05K 2201/0338; H05K 2201/0367; H05K 2201/0382; H05K 2201/09827

(57) ABSTRACT

A printed circuit board includes an insulating layer, and a conductive post disposed on the insulating layer. The conductive post includes a barrier layer, a seed layer disposed on the barrier layer, and a plating layer disposed on the seed layer.

### CROSS-REFERENCE TO RELATED APPLICATION(S)

This application claims benefit of priority to Korean Patent Application No. 10-2024-0169768 filed on Nov. 25, 2024 in the Korean Intellectual Property Office, the disclosure of which is incorporated herein by reference in its entirety.

### TECHNICAL FIELD

The present disclosure relates to a printed circuit board.

In response to the recent trend for miniaturization and weight reductions in mobile devices, there is an increasing need to achieve miniaturization and weight reduction in printed circuit boards (PCBs) mounted in such devices. As mobile devices have reduced weights and sizes, an undercut phenomenon may occur during the fabrication of microcircuits, which may lead to defects in the microcircuits. To meet such technical demands, research has been continuously conducted to improve the reliability of microcircuits while implementing microcircuits with reduced linewidths and distances therebetween.

### SUMMARY

An aspect of the present disclosure is to provide a printed circuit board including a conductor layer having improved loss characteristics.

Another aspect of the present disclosure is to provide a printed circuit board including a conductive post having improved uniformity.

According to an aspect of the present disclosure, there is provided a printed circuit board including an insulating layer, and a conductive post disposed on the insulating layer. The conductive post may include a barrier layer, a seed layer disposed on the barrier layer, and a plating layer disposed on the seed layer.

The barrier layer may include Ni.

A side surface of the barrier layer and a side surface of the seed layer may be discontinuous.

A minimum width of the barrier layer may be greater than a minimum width of the seed layer.

A side surface of the barrier layer may be spaced apart from an internal surface of the insulating layer facing the conductive post.

A lower surface of the barrier layer may be positioned below an upper surface of the insulating layer.

An upper surface of the barrier layer may be positioned on a level, the same as that of an upper surface of the insulating layer.

A side surface of the seed layer and a side surface of the plating layer may include a curved surface.

The side surface of the seed layer and the side surface of the plating layer may be continuous.

A width of the plating layer may gradually decrease from an upper portion thereof to a lower portion thereof.

A width of the seed layer may gradually increase from an upper portion thereof to a lower portion thereof.

The printed circuit board may further include an additional barrier layer disposed on the plating layer.

The additional barrier layer may include at least one of Au, Ni, and Pt.

A width of the additional barrier layer may be greater than a width of the plating layer.

An end of the additional barrier layer may extend to cover a portion of a side surface of the plating layer.

The plating layer may include a first plating layer and a second plating layer disposed on the first plating layer.

A side surface of the first plating layer may have a slope, greater than that of a side surface of the second plating layer, in a thickness direction of the insulating layer.

In a printed circuit board according to some example embodiments of the present disclosure, a conductor layer may have improved loss characteristics. In addition, the conductive post having improved uniformity may contribute to improvement in performance of the printed circuit board.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIG. 3 is a schematic plan view of an example of a printed circuit board;

FIGS. 4 to 7 illustrate examples of a method of manufacturing a printed circuit board;

FIG. 8 is a schematic cross-sectional view of another example of a printed circuit board;

FIGS. 9 and 10 illustrate examples of a method of manufacturing a printed circuit board;

FIG. 11 is a schematic cross-sectional view of another example of a printed circuit board; and

FIG. 12 is a schematic cross-sectional view of another example of a printed circuit board.

### DETAILED DESCRIPTION

Hereinafter, some example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

### Electronic Device

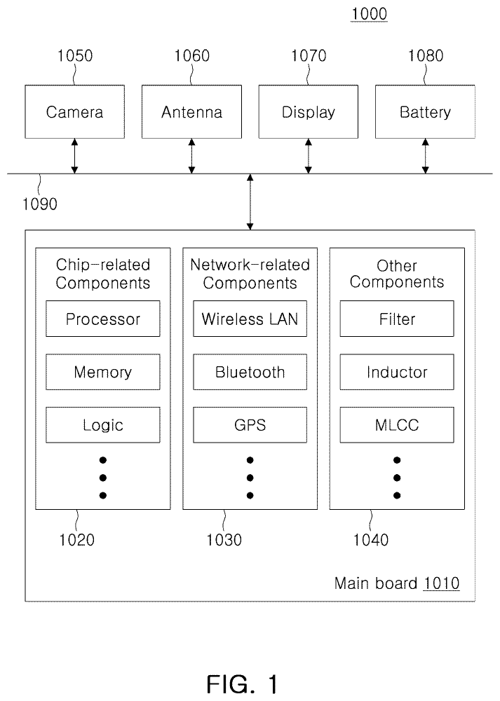

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

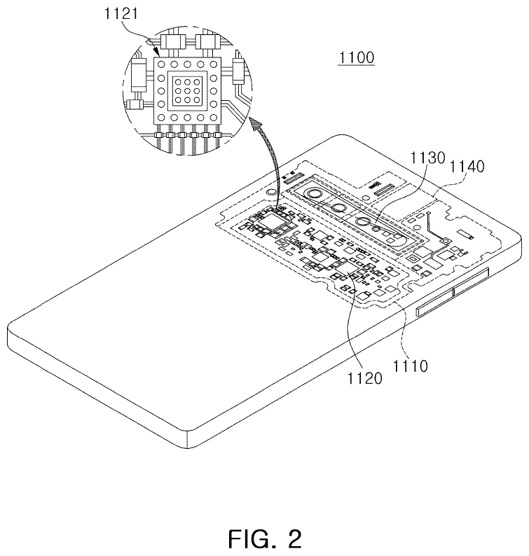

FIG. 2 is a schematic perspective view of an example of an electronic device.

Referring to the drawings, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not limited to the smartphone 1100, and may be other electronic devices, as described above.

### Printed Circuit Board

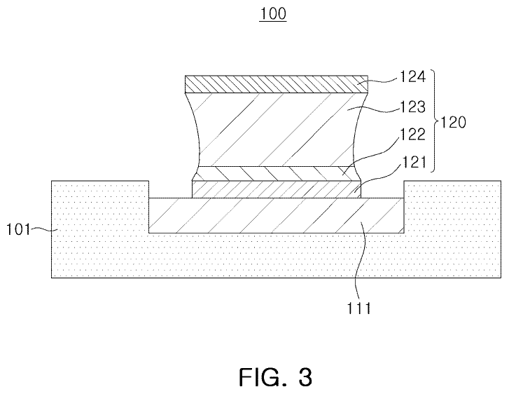

FIG. 3 is a schematic plan view of an example of a printed circuit board. Referring to FIG. 3, a printed circuit board 100 according to the some example embodiments of the present disclosure may include an insulating layer 101 and a conductive post 120. Here, the conductive post 120 may have a multilayer structure. Specifically, the conductive post 120 may include a barrier layer 121, a seed layer 122, and a plating layer 123. In addition, the conductive post 120 may further include an additional barrier layer 124 on the plating layer 123. As the barrier layer 121 is provided below the seed layer 122 and the plating layer 123, a conductor layer 111 may be protected during an etching process of the seed layer 122, thereby reducing surface roughness variations of the conductor layer 111 and minimizing thickness variations of the conductive post 120. Hereinafter, main components of the printed circuit board 100 will be described in detail.

The insulating layer 101 may include an insulating material, and may have a multilayer structure. Here, the insulating material of the insulating layer 101 may include a thermosetting resin such as an epoxy resin, a thermoplastic resin such as polyimide, or a material including an inorganic filler, an organic filler, and/or a glass fiber (glass cloth, and/or glass fabric), together with the above-described resins. The insulating material may include a photosensitive material and/or a non-photosensitive material. For example, the insulating material may include such as a solder resist (SR), an Ajinomoto build-up film (ABF), bismaleimide triazine (FR-4), prepreg (PPG), or resin-coated copper (RCC), an insulating material such as a copper lad laminate (CCL), or the like, but the present disclosure is not limited thereto, and other polymer materials may be used.

The conductor layer 111 may be disposed in the insulating layer 101. The conductor layer 111 may include a metal having high electrical conductivity, for example, at least one selected from the group consisting of copper (Cu), aluminum (Al), silver (Ag), tin (Sn), gold (Au), nickel (Ni), lead (Pb), titanium (Ti), and alloys thereof, and may have a multilayer structure, as necessary. In addition, the insulating layer 101 may further include a conductive layer, a pad, a conductive via, or the like, disposed on a level, the same as or different from that of the conductor layer 111, in addition to the conductor layer 111.

The conductive post 120 may be disposed on the insulating layer 101. In this case, the conductive post 120 may be disposed on the conductor layer 111, and may be connected to the conductor layer 111. When the conductive post 120 is disposed on the insulating layer 101, the conductive post 120 may not need to be disposed on an upper surface of the insulating layer 101, and at least a portion of the conductive post 120 may be positioned below the upper surface of the insulating layer 101. The conductive post 120 may include a barrier layer 121, a seed layer 122 disposed on the barrier layer 121, and a plating layer 123 disposed on the seed layer 122. The barrier layer 121 may function as an etch stop layer protecting the conductive layer 111 or the like during a process of etching the seed layer 122 to form the conductive post 120. Accordingly, the barrier layer 121 may include a material having etching characteristics different from those of the seed layer 122 and the plating layer 123 disposed thereon. For example, the seed layer 122 and the plating layer 123 may include Cu, and the barrier layer 121 may include a material such as Ni or Au. In consideration of a case in which the barrier layer 121 is etched and removed in a subsequent process, the barrier layer 121 may be implemented as a layer including nickel (Ni). The presence of the barrier layer 121 may protect the conductive layer 111 during an etching process of the seed layer 122. As a result, surface roughness variation of the conductive layer 111 may be reduced, and a risk of signal loss in the conductive layer 111 may be reduced.

As described above, when the barrier layer 121 functions as an etch stop layer, a side surface of the barrier layer 121 and a side surface of the seed layer 122 may have a discontinuous shape after the etching process. In addition, a minimum width of the barrier layer 121 may be greater than a minimum width of the seed layer 121 after the etching process. In this case, an uppermost portion of the seed layer 121 may have a minimum width. That is, a width of the seed layer is gradually decreased from the bottom to the top. Here, widths of the barrier layer 121, the seed layer 122, and the plating layer 123 to be described below may be defined as widths in a direction, perpendicular to a thickness direction of the insulating layer 101 (a horizontal direction based in the drawings), and may be measured in one cross-section of the printed circuit board 100. In this case, to enhance width measurement accuracy, a value obtained by averaging widths obtained from a plurality of cross-sections may be used.

Referring to a shape of the barrier layer 121 in more detail, the side surface of the barrier layer 121 may be spaced apart from the insulating layer 101. That is, as illustrated in FIG. 3, the side surface of the barrier layer 121 may be spaced apart from an internal surface of the insulating layer 101 facing the conductive post 120, and such a structure may be obtained during a process of selectively etching a portion of the barrier layer 121. In addition, a lower surface of the barrier layer 121 may be positioned below the upper surface of the insulating layer 101. In this case, the upper surface of the barrier layer 121 may be positioned on a level, the same as that of the upper surface of the insulating layer 101. Such an arrangement may be achieved by forming the barrier layer 121 on the conductor layer 111 before forming the seed layer 122 on the insulating layer 101.

The seed layer 122 and the plating layer 123 may be included in a main body of the conductive post 120, and the seed layer 122 may function as a seed for forming the plating layer 123. The plating layer 123 may be formed using a plating process, for example, an electroplating process, with the seed layer 122 serving as a seed. As a specific process example, the plating layer 123 may be formed by panel plating over a plurality of conductive posts 120 or a plurality of printed circuit boards 100 and then individualized using an etching process. When the plating layer 123 is obtained by plating the plating layer 123 in a panel plating form on a large area, the plating layer 123 may have reduced thickness variation, thereby enhancing the uniformity of the conductive post 120. A metal material of the seed layer 122 and a metal material of the plating layer 123 may be the same, but the present disclosure is not limited thereto, and the seed layer 122 and the plating layer 123 may include different metal materials. For example, each of the seed layer 122 and the plating layer 123 may be a metal layer including copper (Cu), but the present disclosure is not limited thereto. As another example, the seed layer 122 may include a material selected from the group consisting of, such as, aluminum (Al), silver (Ag), tin (Sn), gold (Au), nickel (Ni), lead (Pb), titanium (Ti), and alloys thereof, and the plating layer 123 may include copper (Cu). That is, the seed layer 122 and the plating layer 123 may include different metal materials.

As described above, the conductive posts 120 may be etched and individualized using the barrier layer 121 as an etch stop layer, and a side surface of the seed layer 122 and a side surface of the plating layer 123 may include a curved surface as a result of the etching process. The seed layer 122 and the plating layer 123 may be simultaneously etched without etching each separately. In this case, the side surface of the seed layer 122 and the side surface of the plating layer 123 may be continuous. In addition, the plating layer 123 may have a width gradually decreasing from an upper portion thereof to a lower portion thereof. Conversely, the seed layer 122 may have a width gradually increasing from an upper portion thereof to a lower portion thereof.

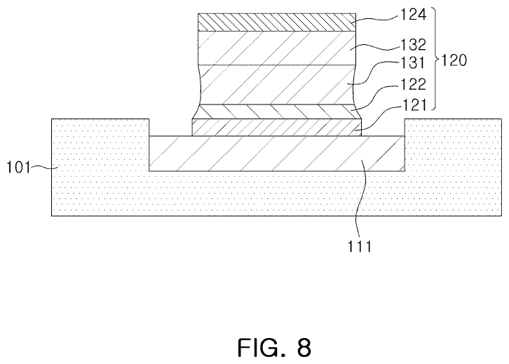

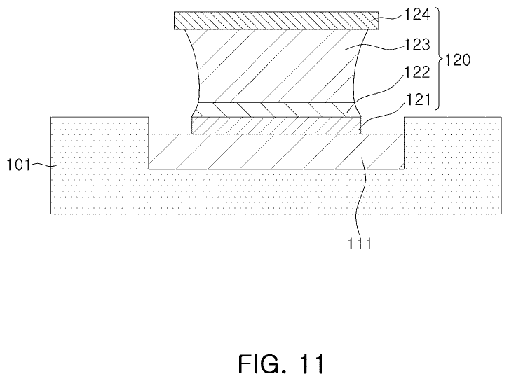

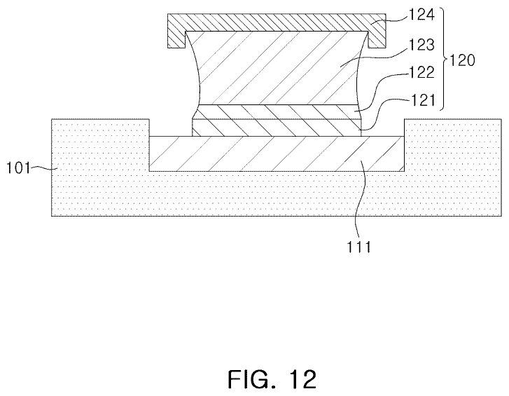

An additional barrier layer 124 may be provided on the plating layer 123. When the seed layer 122 and the plating layer 123 are etched, the additional barrier layer 124 may function as an etching mask, and may remain as a component of the conductive post 120 after the etching process. In consideration of such a function, the additional barrier layer 124 may include at least one of Au, Ni, and Pt. The barrier layer 124 may be modified to perform an efficient etching process. That is, as illustrated in the modification of FIG. 11, a width of the additional barrier layer 124 may be greater than a width of the plating layer 123. In addition, as illustrated in the modification of FIG. 12, an end of the additional barrier layer 124 may extend to cover a portion of a side surface of the plating layer 123. Any modifications as illustrated in FIG. 11 and FIG. 12 may also be applied to the example embodiment of FIG. 8.

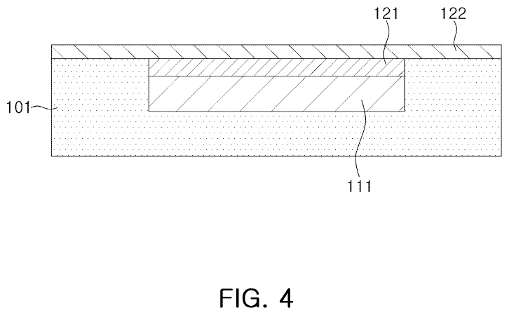

An example of a method of manufacturing a printed circuit board will be described with reference to FIGS. 4 to 7, based on a process of forming a conductive post. First, referring to FIG. 4, a conductor layer 111 and a barrier layer 121 may be formed on an insulating layer 101, and a seed layer 122 may be formed thereon. In this case, the conductor layer 111 and the barrier layer 121 may be formed such that at least a portion thereof is buried in the insulating layer 101, and the barrier layer 121 may be formed to have a width, equal to that of the conductor layer 111. The conductor layer 111 and the barrier layer 121 may be formed using a conductor pattern formation process known in the art, such as a semi-additive process (SAP), a modified semi-additive process (MSAP), a tenting (TT) process, and a subtractive process. The seed layer 122 may be formed by electroless plating of copper (Cu) or may be attached to the insulating layer 101 in the form of a copper foil.

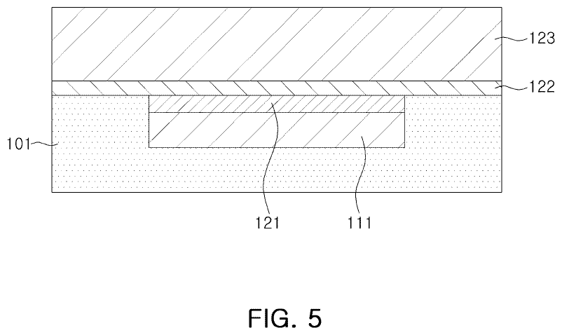

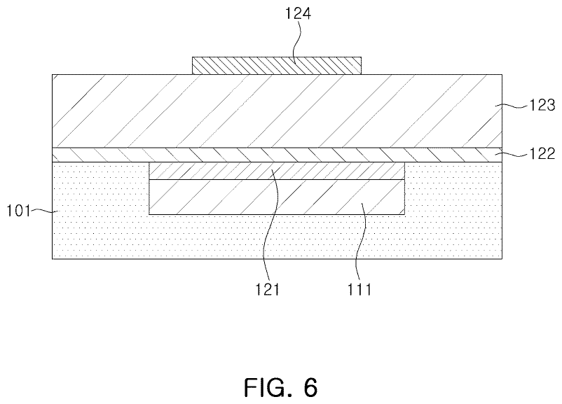

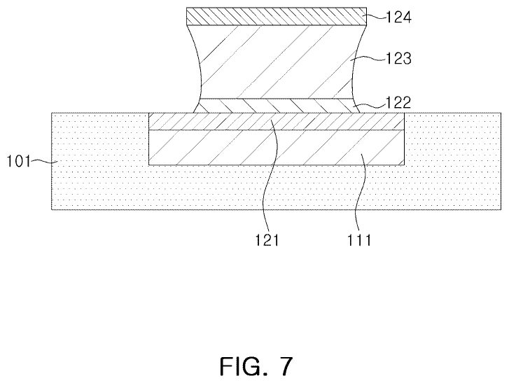

Subsequently, as illustrated in FIG. 5, a plating layer 123 may be formed on the seed layer 122. As described above, the plating layer 123 may be formed by panel plating over a plurality of conductive posts 120 or a plurality of printed circuit boards 100. In this case, the plating layer 123 may be formed to have a relatively large thickness, and may have reduced thickness variation according to a conductive post 120. Subsequently, as illustrated in FIG. 6, an additional barrier layer 124 may be formed, and the additional barrier layer 124 may function as a mask during a subsequent etching process. In this case, the additional barrier layer 124 may be selectively formed in a region corresponding to a region in which the conductive post 120 is to be formed. Subsequently, as illustrated in FIG. 7, portions of the seed layer 122 and the plating layer 123 may be removed to form a conductive post. For the etching process of the seed layer 122 and the plating layer 123, a wet process or a dry process known in the art may be used. For example, an etchant, reacting selectively with the seed layer 122 and the plating layer 123 without reacting with the barrier layers 121 and 124, may be applied. Subsequently, a selective etching process of removing a portion of the barrier layer 121 may be applied to implement a conductive post 120 that is in the form illustrated in FIG. 3.

With reference to FIG. 8, another form of the conductive post will be described. In the example embodiment of FIG. 8, in a conductive post 120, a plating layer may include a first plating layer 131 and a second plating layer 132, and the remaining components may be implemented in the same form as described above. The first plating layer 131 and the second plating layer 132 may be formed using different plating processes. Specifically, the first plating layer 131 may be formed using the panel plating process described above, and the second plating layer 132 may be formed using a pattern plating process. In this case, as illustrated, a side surface of the first plating layer 131 may have a slope, greater than that of a side surface of the second plating layer 132, in a thickness direction of the insulating layer 101 (that is, a vertical direction in the drawings). A difference between the side surface slopes of the first and the second plating layers 131 and 132 may be obtained during a process in which the first plating layer 131 is selectively etched.

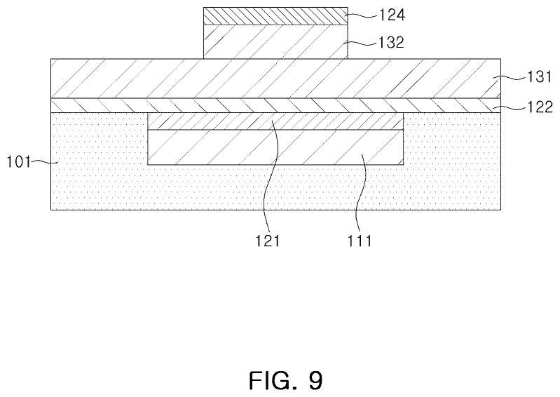

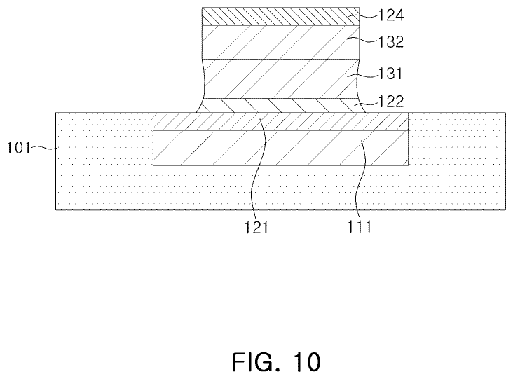

With reference to FIGS. 9 and 10, another example of a method of manufacturing a printed circuit board will be described, and FIGS. 9 and 10 illustrate a process of forming the conductive post of FIG. 8. A first plating layer 131 may be formed on a seed layer 122. For example, the first plating layer 131 may be formed by panel plating over a plurality of conductive posts 120 or a plurality of printed circuit boards 100. In this case, as compared to a process of formatting the plating layer 123 of FIG. 5, the first plating layer 131 may be formed to have a relatively small thickness. Subsequently, a second plating layer 132 may be formed on the first plating layer 131, and the second plating layer 132 may be formed in a form of being separated from those belonging to other conductive posts, that is, in a patterned form. To this end, the second plating layer 132 may be formed by pattern plating. Subsequently, as illustrated in FIG. 10, portions of the seed layer 122, the first plating layer 131, and the second plating layer 132 may be removed to form a conductive post. For the etching process of the seed layer 122, the first plating layer 131, and the second plating layer 132, a wet process or a dry process known in the art may be used. For example, an etchant, reacting selectively with the seed layer 122, the first plating layer 131, and the second plating layer 132 without reacting with the barrier layers 121 and 124, may be applied. Subsequently, a selective etching process of removing a portion of the barrier layer 121 may be applied to implement a conductive post 120 that is in the form illustrated in FIG. 8.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
an insulating layer; and
a conductive post disposed on the insulating layer,
wherein the conductive post includes a barrier layer, a seed layer disposed on the barrier layer, and a plating layer disposed on the seed layer.

2. The printed circuit board of claim 1, wherein the barrier layer includes Ni.

3. The printed circuit board of claim 1, wherein a side surface of the barrier layer and a side surface of the seed layer are discontinuous.

4. The printed circuit board of claim 1, wherein a minimum width of the barrier layer is greater than a minimum width of the seed layer.

5. The printed circuit board of claim 1, wherein a side surface of the barrier layer is spaced apart from an internal surface of the insulating layer facing the conductive post.

6. The printed circuit board of claim 1, wherein a lower surface of the barrier layer is positioned below an upper surface of the insulating layer.

7. The printed circuit board of claim 6, wherein an upper surface of the barrier layer is positioned on the same level as a level of an upper surface of the insulating layer.

8. The printed circuit board of claim 1, wherein a side surface of the seed layer and a side surface of the plating layer include a curved surface.

9. The printed circuit board of claim 8, wherein the side surface of the seed layer and the side surface of the plating layer connected to be a continuous surface.

10. The printed circuit board of claim 1, wherein a width of the plating layer gradually decreases from an upper portion thereof to a lower portion thereof.

11. The printed circuit board of claim 1, wherein a width of the seed layer gradually increases from an upper portion to a lower portion.

12. The printed circuit board of claim 1, further comprising:
an additional barrier layer disposed on the plating layer.

13. The printed circuit board of claim 12, wherein the additional barrier layer includes at least one of Au, Ni, or Pt.

14. The printed circuit board of claim 12, wherein a width of the additional barrier layer is greater than a width of the plating layer.

15. The printed circuit board of claim 12, wherein an end of the additional barrier layer extends to cover a portion of a side surface of the plating layer.

16. The printed circuit board of claim 1, wherein the plating layer includes a first plating layer and a second plating layer disposed on the first plating layer.

17. The printed circuit board of claim 16, wherein a side surface of the first plating layer has a slope, greater than that of a side surface of the second plating layer, in a thickness direction of the insulating layer.
